(19) United States
(12) Patent Application Publication
(10) Pub. No.: US 2012/0273436 A1
(43) Pub. Date: Nov. 1, 2012

(54) DATA CENTER CONTAINER

(75) Inventor: GANG-QIANG QIN, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/440,513

(22) Filed: Apr. 5, 2012

(30) Foreign Application Priority Data
Apr. 29, 2011 (CN) 201110110497.9

(51) Int. Cl. H05K 7/18; H05K 7/20

(52) U.S. Cl. 211/26

(57) ABSTRACT

A data center container includes a top frame. The top frame includes a first pole. The bottom frame includes a third pole. Two supports are secured to the top frame and the bottom frame. The supporting pole is secured to the two supports between the first pole and the second pole. A plurality of first plates is secured to the supporting pole and the third pole. A plurality of second plates is secured to the supporting pole and the third pole. The first plates are secured to the second plates.

### BACKGROUND

1. Technical Field

The present disclosure relates to containers, and particularly to a data center container.

2. Description of Related Art

Many data center containers are modified by a intermodal container, also known as a shipping container. The intermodal container includes a top plate, a bottom plate and four side plates connected between the top plate and the bottom plate. Each side plate is made of a flat metal plate. However, if the data center container is modified by the intermodal container, the structural strength of the flat side plates does not meet the structural strength requirement of the data center container when the data center container is moved. Therefore, there is room for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of a data center container in accordance with an embodiment.

FIG. 2 is an isometric view of a first plate of the data center container of FIG. 1.

FIG. 3 is an isometric view of a second plate of the data center container of FIG. 1.

FIG. 4 is a cutaway, cross-sectional view of the data center container of FIG. 1, taken along the line IV-IV.

FIG. 5 is an assembled view of the data center container of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

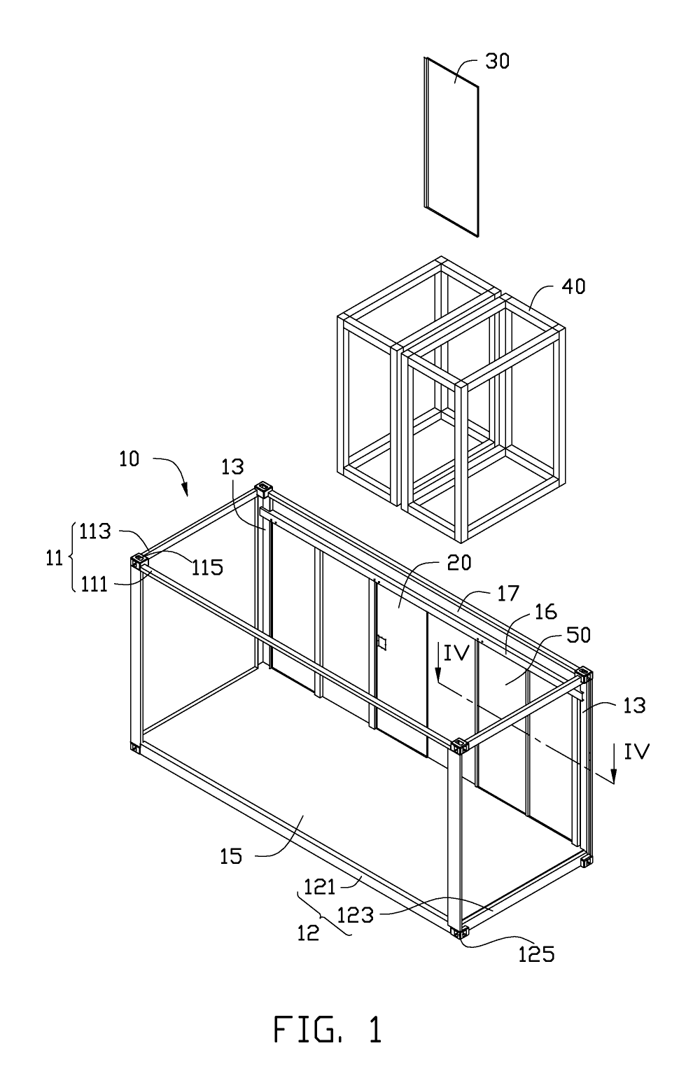

Referring to FIG. 1, a data center container in accordance with an embodiment includes an enclosure 10 and a plurality of server racks 40 (only two shown in FIG. 1). Each of the plurality of server racks 40 can receive a plurality of server systems. In an embodiment, the data center container is an enclosure of a cloud computing server.

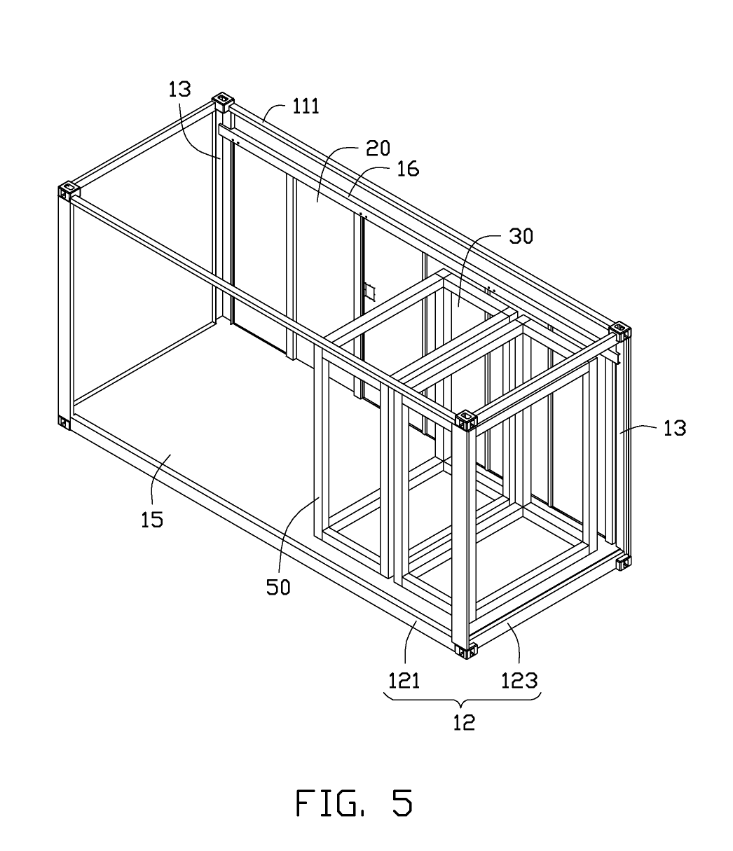

The enclosure 10 includes a top frame 11, a bottom frame 12, and four supports 13 connected to the top frame 11 and the bottom frame 12. The top frame 11 includes two first poles 111 and two second poles 113. Each first pole 111 is connected to the two second poles 113. The two first poles 111 are substantially perpendicular to the two second poles 113. A first joint 115 is defined between each first pole 111 and each second pole 113. The bottom frame 12 includes two third poles 121 and two fourth poles 123. Each third pole 121 is connected to the two fourth poles 123. The two third poles 121 are substantially perpendicular to the two fourth poles 123 and the two second poles 113 and parallel to the two first poles 111. A second joint 125 is defined between each third pole 121 and each fourth pole 123. Each support 13 is connected to the first joint 115 and the second joint 125. The four supports 13 are substantially perpendicular to each of the two first poles 111, the two second poles 113, the two third poles 121 and the fourth poles 123. A bottom board 15 is secured to the bottom frame 12, and the server racks 40 are secured to the bottom board 15 (see FIG. 5).

The enclosure 10 further includes a supporting pole 16, a door 20, a plurality of first plates 20 and a plurality of second plates 50. In the enclosure 10, the supporting pole 16, the door 20, the plurality of first plates 20 and the plurality of second plates 50 can be located in each of opposite sides of the enclosure. FIG. 1 only shows the door 20, the plurality of first plates 20 and the plurality of second plates 50 located in one side of the enclosure 10. The supporting pole 16 is secured to two of the four supports 13. The two first poles 111 and the third poles 113 are substantially parallel to the supporting pole 16. The two second poles 113, the fourth poles 123, and the four supports 13 are substantially perpendicular to the supporting pole 16. An opening 17 is defined between the first pole 111 and the supporting pole 16. The door 20, the plurality of first plates 30, and the plurality of second plates 50 are secured between the supporting pole 16 and the first pole 121.

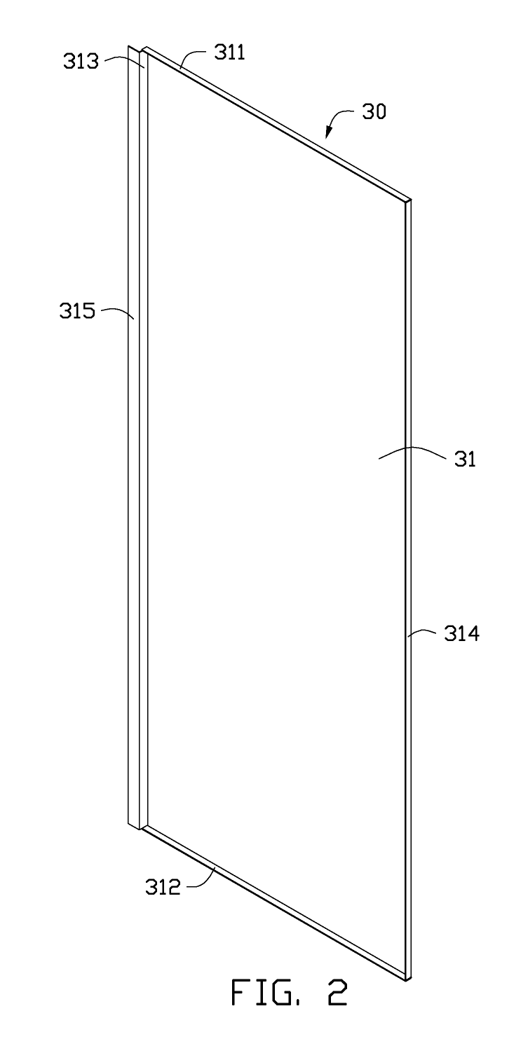

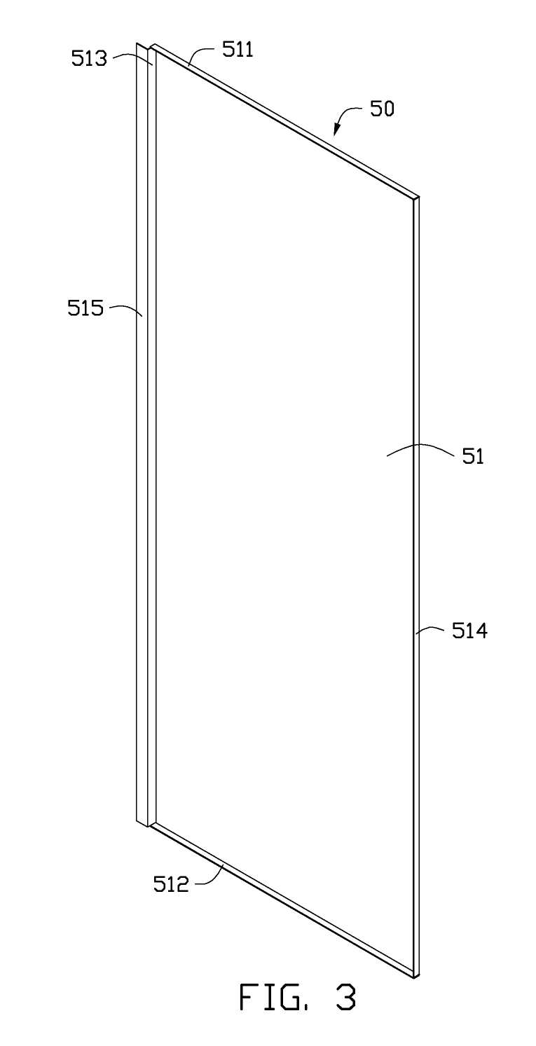

Referring to FIG. 2, each first plate 30 includes a base body 31, a first flange 311, a second flange 312, a third flange 313 and a fourth flange 314. The first flange 311, the second flange 312, the third flange 313 and the fourth flange 314 substantially perpendicularly extend from four edges of the base body 31. A positioning piece 315 extends from the third flange 313, and the positioning piece 315 is substantially parallel to the base body 31. Referring to FIG. 3, each second plate 50 includes a main body 51, a first rim 511, a second rim 512, a third rim 513 and a fourth rim 514. The first rim 511, the second rim 512, the third rim 513 and the fourth rim 514 substantially perpendicularly extend from the main body 51. A retaining piece 515 extends outward from the third rim 513, and the retaining piece 515 is substantially parallel to the main body 51.

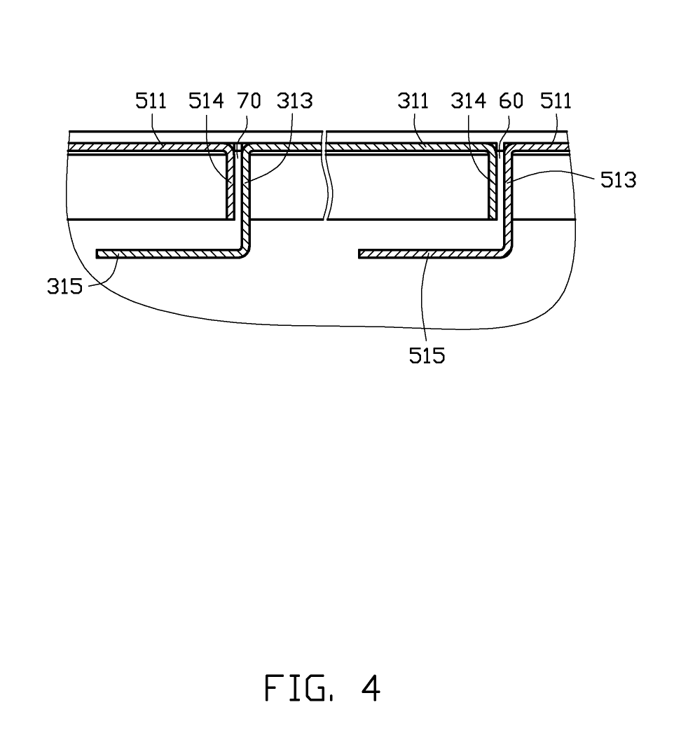

Referring to FIGS. 1, 4 and 5, in assembly, the door 20, the first plates 30 and the second plates 50 are secured between the supporting pole 16 and the third pole 121. The first plates 30 and the second plates 50 are located on opposite sides of the door 20.

The fourth flange 314 of the first plate 30 is adjacent the third rim 513 of the second plate 50, and a first gap 60 is defined between the fourth flange 314 and the third rim 513. The fourth rim 514 of the second plate 50 is adjacent the third flange 313 of the first plate 30, and a second gap 70 is defined between the fourth rim 514 and the third flange 313. The positioning piece 315 is located in the enclosure 10 and extends to an inside of the second plate 50. The retaining piece 515 is located in the enclosure 10 and extends to an inside of the first plate 30. The fourth flange 314 is located in a corner between the third rim 513 and the retaining piece 515, and the fourth rim 514 is located in a corner between the third flange 313 and the positioning piece 315. When the first plate 30 and the second plate 50 are welded together, the welded material is received in the first gap 60 and the second gap 70.

In the enclosure 10, the plurality of first plates 30 and the plurality of second plates 50 are assembled in turn. The server rack 40 are secured in the enclosure 10 on the bottom board 15.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. A data center container comprising:
a top frame, the top frame comprising a first pole;
a bottom frame, the bottom frame comprising a third pole;
two supports secured to the top frame and the bottom frame;
a supporting pole secured to the two supports between the first pole and the third pole;
a plurality of first plates secured to the supporting pole and the third pole; each of the plurality of first plates comprises a base body, a third flange, a fourth flange and a positioning piece; the third flange and the fourth flange extend from opposite edges of the base body and are located between the first pole and the third pole; and
a plurality of second plates secured to the supporting pole and the third pole; each of the plurality of second plates comprises a main body, a third rim, a fourth rim and a retaining piece; the third rim and the fourth rim extend from opposite edges of the main body and are located between the first pole and the third pole;
wherein the fourth flange of one of the plurality of first plates is positioned in a first corner between the third rim and the retaining piece of one of the plurality of second plates, and the fourth rim of one of the plurality of second plates is positioned in a second corner between the third flange and the positioning piece of one of the plurality of first plates.

2. The data center container of claim 1, wherein a first gap is defined between the fourth flange of one of the plurality of first plates and the third rim of one of the plurality of second plates, and the first gap is configured for receiving a welded material when the one of the plurality of first plates is welded to the one of the plurality of second plates.

3. The data center container of claim 1, wherein a second gap is defined between the fourth rim of one of the plurality of second plates and the third flange of one of the plurality of first plates, and the second gap is configured for receiving a welded material when the one of the plurality of first plate is welded to the one of the plurality of second plate.

4. The data center container of claim 1, wherein the first pole is substantially parallel to the third pole, and the supporting pole is substantially parallel to the first pole and the third pole.

5. The data center container of claim 4, wherein the two supports are substantially perpendicular to the first pole and the third pole.

6. The data center container of claim 1, wherein the positioning piece and the retaining piece are located inside of the plurality of first plates and the plurality of second plates.

7. The data center container of claim 1, further comprising a bottom board secured to the bottom frame, wherein a plurality of server rack is secured to the bottom board.

8. The data center container of claim 1, wherein an opening is defined between the first pole and the supporting pole, and the opening is configured for receiving a plurality of fans.

9. The data center container of claim 1, wherein the third flange and the fourth flange of each of the plurality of first plates is substantially perpendicular to the base body, and the positioning piece is substantially parallel to the base body.

10. The data center container of claim 9, wherein each of the plurality of first plates further comprises a first flange and a second flange extending from opposite edges of the base body; and the first flange and the second flange is substantially perpendicular to the base body, the third flange, and the fourth flange.

11. The data center container of claim 1, wherein the third rim and the fourth rim of each of the plurality of second plates is substantially perpendicular to the main body; the retaining piece is substantially parallel to the main body; each of the plurality of second plates further comprises a first rim and a second rim extending from opposite edges of the main body; and the first rim and the second rim is substantially perpendicular to the main body, the third rim, and the fourth rim.

12. A data center container comprising:
a top frame, the top frame comprising two first poles and two second poles, each of the two first poles are connected to the two second poles;
a bottom frame, the bottom frame comprising two third poles and two fourth poles, each of the two third poles are connected to the two fourth poles;
four supports secured to the top frame and the bottom frame, one end of each of the four supports connected to a first joint between each of the two first poles and each of the two second poles, and an opposite end connected to a second joint between each of the two third poles and each of the two fourth poles;
two supporting poles, each of the two supporting poles secured to adjacent two of the four supports between the corresponding one of the two first poles and the corresponding one of the two third poles;
a plurality of first plates secured between each of the two supporting poles and each of the two third poles; each of the plurality of first plates comprising a positioning piece; and
a plurality of first plates and a plurality of second plates secured between each of the two supporting poles and each of the two third poles, and each of the plurality of first plates secured to a corresponding one of the plurality of second plates.

13. The data center container of claim 12, wherein each of the plurality of first plates comprising a base body, a third flange, a fourth flange and a positioning piece; the third flange and the fourth flange extend from opposite edges of the base body and located between one of the two first poles and adjacent one of the two third poles; each of the plurality of second plates comprising a main body, a third rim, a fourth rim and a retaining piece; the third rim and the fourth rim extend from opposite edges of the main body and located between one of the two first poles and adjacent one of the two third poles; and the fourth flange of one of the plurality of first plates is positioned in a first corner between the third rim and the retaining piece of one of the plurality of second plates, and the fourth rim of one of the plurality of second plates is positioned in a second corner between the third flange and the positioning piece of one of the plurality of first plates.

14. The data center container of claim 13, wherein a first gap is defined between the fourth flange of one of the plurality of first plates and the third rim of one of the plurality of second plates, and the first gap is configured for receiving a welded material when the one of the plurality of first plates is welded to the one of the plurality of second plates.

15. The data center container of claim 13, wherein a second gap is defined between the fourth rim of one of the plurality of second plates and the third flange of one of the plurality of first plates, and the second gap is configured for receiving a welded material when the one of the plurality of first plates is welded to the one of the plurality of second plates.

16. The data center container of claim 12, wherein the two first poles are substantially perpendicular to the two second poles and parallel to the two third poles, and the two supporting poles are substantially perpendicular to the two fourth poles and parallel to the two first poles and the two third poles.

17. The data center container of claim 16, wherein the four supports are substantially perpendicular to the two first poles, the two second poles, the two third poles, and the two fourth poles.

18. The data center container of claim 13, wherein the positioning piece of each of the plurality of first plates and the retaining piece of each of the plurality of second plates are located inside of the plurality of first plates and the plurality of second plates.

19. The data center container of claim 12, further comprising a bottom board secured to the bottom frame, wherein a plurality of server rack is secured to the bottom board.

20. The data center container of claim 12, wherein an opening is defined between each of the two first poles and each of the two supporting poles, and each opening is configured for receiving a plurality of fans.
